(19) United States
(12) Patent Application Publication
(10) Pub. No.: US 2012/0231588 A1
(43) Pub. Date: Sep. 13, 2012

(54) MANUFACTURING METHOD OF THIN FILM TRANSISTOR

(76) Inventors: Shin-Chuan Chiang, Taipei City (TW); Yu-Hao Lai, Taichung City (TW); Huai-An Li, Taoyuan County (TW)

(21) Appl. No.: 13/117,130

(22) Filed: May 26, 2011

(30) Foreign Application Priority Data
Mar. 10, 2011 (TW) 100108068

(51) Int. Cl. H01L 21/336

(52) U.S. Cl. 438/158; 257/E21.411

(57) ABSTRACT

A manufacturing method of thin film transistors is provided. The manufacturing method includes: providing a substrate; forming a gate electrode; forming a gate insulating layer; forming a patterned oxide semiconductor layer; forming a source electrode and a drain electrode; and executing a localized laser treatment. A laser beam is used to irradiate at least a part of the patterned oxide semiconductor layer in the localized laser treatment. An electrical resistitivity of the patterned oxide semiconductor layer irradiated by the laser beam is lower than an electrical resistitivity of the patterned oxide semiconductor layer without being irradiated by the laser beam.

### BACKGROUND OF THE INVENTION

1. Field of the Invention

The present invention relates to a manufacturing method of a thin film transistor, and more particularly, to a manufacturing method of a thin film transistor with an oxide semiconductor layer, wherein a localized laser treatment is employed to lower a contact resistance between the oxide semiconductor layer and the source/drain electrode.

2. Description of the Prior Art

In recent years, applications of flat display devices are rapidly developed. Electronics, such as televisions, cell phones, mobiles, and refrigerators, are installed with flat display devices. A thin film transistor (TFT) is a kind of semiconductor devices commonly used in the flat display device, such as a liquid crystal display (LCD), an organic light emitting diode (OLED) display, and an electronic paper (E-paper). The thin film transistor is employed to control voltage and/or current of a pixel of the flat display device for presenting a bright, a dark, or a gray level display effect.

According to different semiconductor materials applied in the thin film transistors, the thin film transistors in current display industries may includes amorphous silicon thin film transistors (a-Si TFTs), poly silicon thin film transistors, and oxide semiconductor thin film transistors. The amorphous silicon thin film transistor is currently the mainstream thin film transistor applied in the display industry because of its mature process techniques and high yield. However, the amorphous silicon thin film transistor may not be good enough to satisfy requirements of foreseeable high performance display devices, because the electrical mobility of the amorphous silicon thin film transistor, which is mainly determined by material properties of amorphous silicon, can not be effectively improved by process tuning or design modification. The typical value of the electrical mobility of the amorphous silicon thin film transistor is smaller than 1 cm²/Vs. On the contrary, the electrical mobility of the poly silicon thin film transistor is much better because of material properties of poly silicon. The typical value of the electrical mobility of the poly silicon thin film transistor is around 100 cm²/Vs. However, because of process issues such as high process complexity and worse uniformity, which is mainly generated by crystallization processes applied to large size substrates, the poly silicon thin film transistors are mainly applied in small size display devices. On the other hand, the oxide semiconductor thin film transistor may be applied for large size substrates without the above-mentioned uniformity issue because the structure of the employed oxide semiconductor material is generally amorphous. The process flexibility of the oxide semiconductor thin film transistor is even better than the amorphous silicon thin film transistor, because the oxide semiconductor material layer may be formed by diverse methods such as sputter depositing, spin-on coating, and inkjet printing. Additionally, the electrical mobility of the oxide semiconductor thin film transistor is generally 10 times larger than the electrical mobility of the amorphous silicon thin film transistor. The typical value of the electrical mobility of the oxide semiconductor thin film transistor is generally between 10 and 50 cm²/Vs. Therefore, the oxide semiconductor thin film transistor is currently the front-runner in the competition of replacing the amorphous silicon thin film transistor in the display industry.

In the structure of the conventional amorphous silicon thin film transistor, an ohmic contact layer is disposed between an amorphous silicon semiconductor layer and source/drain electrodes for improving contact conditions. In the oxide semiconductor thin film transistor, because ohmic contacts may be created directly between the oxide semiconductor layer and specific materials of the source/drain electrodes, such as molybdenum (Mo), aluminum (Al), and indium tin oxide (ITO), the ohmic contact layer may be omitted for the purpose of process reduction. However, a contact resistance between the oxide semiconductor layer and other material of the source/drain electrodes, such as chromium (Cr) or titanium (Ti), is still high, and may influence electrical performances of the oxide semiconductor thin film transistor. Therefore, for loosening the restriction of the adequate materials for the source/drain electrodes in the oxide semiconductor thin film transistor and for enhancing the performance of the oxide semiconductor thin film transistor, the contact resistance issue in the oxide semiconductor thin film transistor has to be further improved.

For improving the contact resistance between the oxide semiconductor layer and the source/drain electrode, a plasma treatment is the most popular method for lowering an electrical resistivity of the oxide semiconductor layer within a region which is going to contact the source/drain electrodes. However, in the plasma treatment, an additional patterned barrier layer is required for protecting other regions of the oxide semiconductor layer. Because extra processes, such as a film deposition, a photo lithography process, and an etching process, are required for forming the patterned barrier layer, the process complexity of manufacturing oxide semiconductor thin film transistor may be increased, and the cost and the yield may be also affected.

### SUMMARY OF THE INVENTION

It is one of the objectives of the present invention to provide a manufacturing method of a thin film transistor. A localized laser treatment is employed to effectively lower the contact resistance between the oxide semiconductor layer and the source/drain electrodes.

According to a preferred embodiment of the present invention, a manufacturing method of a thin film transistor includes: providing a substrate; forming a gate electrode on the substrate; forming a gate insulating layer on the substrate; forming a patterned oxide semiconductor layer on the substrate; forming a source electrode and a drain electrode on the substrate; and executing a localized laser treatment. A laser beam is employed to irradiate at least a part of the patterned oxide semiconductor layer in the localized laser treatment. An electrical resistitivity of the patterned oxide semiconductor layer irradiated by the laser beam is lower than an electrical resistitivity of the patterned oxide semiconductor layer without being irradiated by the laser beam. At least a part of the patterned oxide semiconductor layer irradiated by the laser beam contacts the source electrode or the drain electrode.

In the present invention, the localized laser treatment is employed to selectively lower the electrical resistivity of the oxide semiconductor layer within specific regions. The purpose of lowering the contact resistance between the oxide semiconductor layer and the source/drain electrodes and enhancing the performance of the oxide semiconductor thin film transistor may then be achieved. In addition, the restriction of the adequate materials for the source/drain electrodes in the oxide semiconductor thin film transistor may be relaxed, and the flexibility of the manufacturing process may also be improved.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-3 are schematic diagrams illustrating a manufacturing method of a thin film transistor according to the first preferred embodiment of the present invention.

FIGS. 4-5 are schematic diagrams illustrating a manufacturing method of a thin film transistor according to the second preferred embodiment of the present invention.

FIGS. 6-7 are schematic diagrams illustrating a manufacturing method of a thin film transistor according to the third preferred embodiment of the present invention.

FIG. 8 is a schematic diagram illustrating a thin film transistor according to the fourth preferred embodiment of the present invention.

FIGS. 9-10 are schematic diagrams illustrating a manufacturing method of the thin film transistor according to a fifth preferred embodiment of the present invention.

### DETAILED DESCRIPTION

Certain terms are used throughout the description and following claims to refer to particular components. As one skilled in the art will understand, electronic equipment manufacturers may refer to a component by different names. This document does not intend to distinguish between components that differ in name but not function. In the following description and in the claims, the terms “include” and “include” are used in an open-ended fashion, and thus should be interpreted to mean “include, but not limited to . . . ” In addition, to simplify the descriptions and make it more convenient to compare between each embodiment, identical components are marked with the same reference numerals in each of the following embodiments. Please note that the figures are only for illustration and the figures may not be to scale.

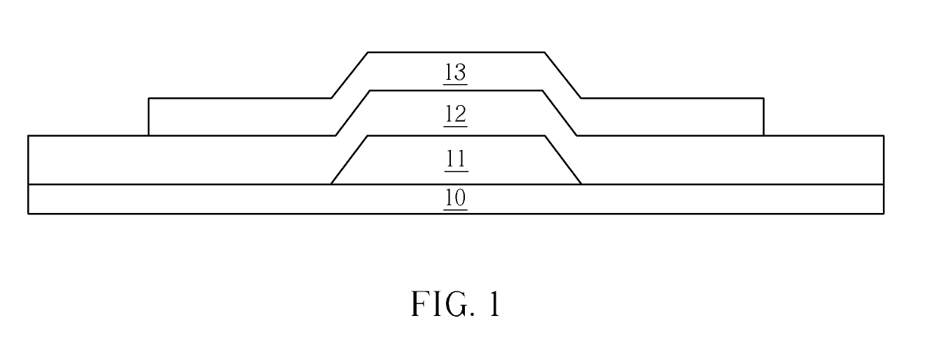

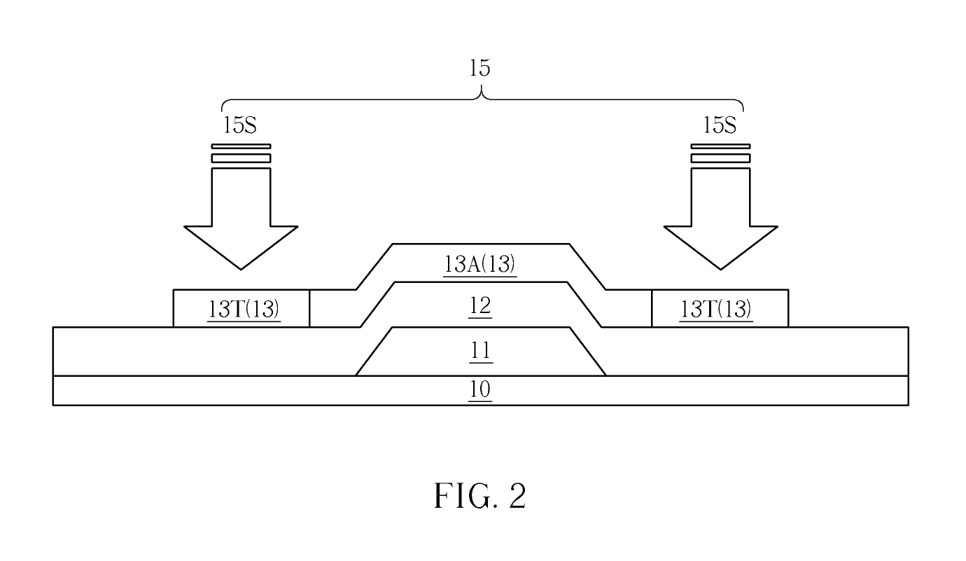

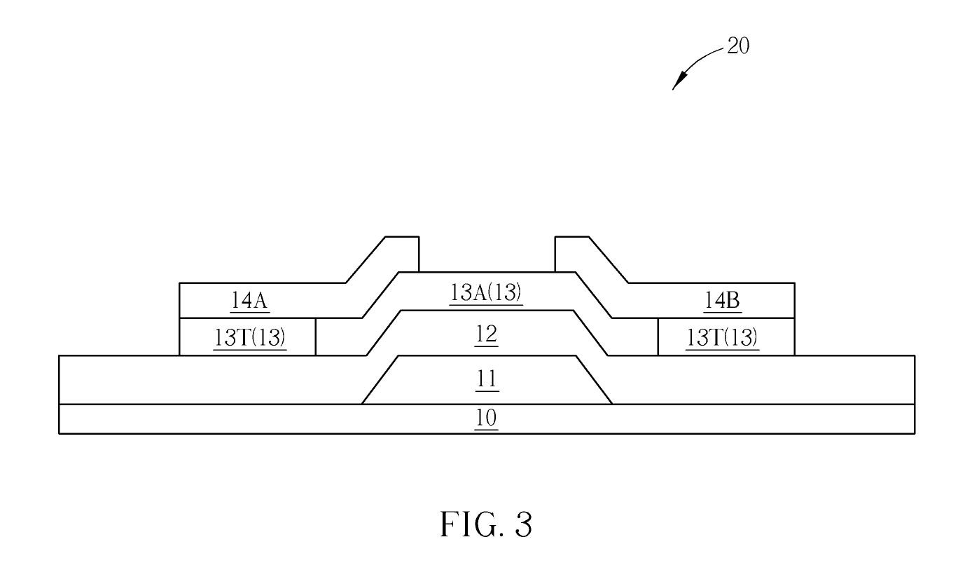

Please refer to FIGS. 1-3. FIGS. 1-3 are schematic diagrams illustrating a manufacturing method of a thin film transistor according to the first preferred embodiment of the present invention. In this embodiment, a thin film transistor 20 is an inverted staggered thin film transistor. As shown in FIGS. 1-3, the manufacturing method of this embodiment includes following steps. Firstly, a substrate 10 is provided. In this embodiment, the substrate 10 includes a rigid substrate, such as a glass substrate, a flexible substrate, and other adequate substrates, for requirements of different display devices. A gate electrode 11 is then formed on the substrate 10. A gate insulating layer 12 is formed and covers the gate electrode 11 and the substrate 10. A patterned oxide semiconductor layer 13 is then formed on the gate insulating layer 12. As shown in FIG. 2, a localized laser treatment 15 is then executed on parts of the patterned oxide semiconductor layer 13. A laser beam 15S is employed to irradiate parts of the patterned oxide semiconductor layer 13. In this embodiment, the patterned oxide semiconductor layer 13 within a region 13T is irradiated by the laser beam 15S, and the patterned oxide semiconductor layer 13 within a region 13A is not irradiated by the laser beam 15S. An electrical resistitivity of the patterned oxide semiconductor layer 13 within the region 13T is lower than an electrical resistitivity of the patterned oxide semiconductor layer 13 within the region 13A. As shown in FIG. 3, a source electrode 14A and a drain electrode 14B are then formed on the substrate 10. At least a part of patterned the oxide semiconductor layer 13 within the region 13T contacts the source electrode 14A or the drain electrode 14B. In this embodiment, the source electrode 14A and the drain electrode 14B entirely cover the patterned oxide semiconductor layer 13 within the region 13T and partially cover the patterned oxide semiconductor layer 13 within the region 13A. In other embodiments of the present invention, the source electrode 14A and the drain electrode 14B may partially cover the patterned oxide semiconductor layer 13 within the region 13T or the source electrode 14A and the drain electrode 14B may extend to contact the gate insulating layer 12. It is worth noticing that, in this embodiment, a range of the region 13T may be defined without additional masks because the localized laser treatment 15 may be selectively executed on specific regions. The range of the region 13T may be controlled by simply modifying process parameters of the localized laser treatment 15. Compared with a plasma treatment and other required additional processes, such as a vacuum deposition, a photo lithography process, and an etching process, the localized laser treatment 15 has merits such as process simplification and better process flexibility. Additionally, in this embodiment, a wavelength range of the laser beam 15S in the localized laser treatment 15 is preferably between 250 nanometers and 500 nanometers for effectively lowering the electrical resistivity of the patterned oxide semiconductor layer 13 within the region 13T, but the wavelength range of the laser beam 15S in the present invention is not limited to this and may be further modified according to different materials of the patterned oxide semiconductor layer 13 or other considerations. In the present invention, the patterned oxide semiconductor layer 13 may include II-VI compounds (such as zinc oxide, ZnO), II-VI compounds doped with alkaline-earth metals (such as zinc magnesium oxide, ZnMgO), II-VI compounds doped with IIIA compounds (such as indium gallium zinc oxide, IGZO), II-VI compounds doped with VA compounds (such as stannum stibium oxide, SnSbO₂), II-VI compounds doped with VIA compounds (such as zinc selenium oxide, ZnSeO), II-VI compounds doped with transition metals (such as zinc zirconium oxide, ZnZrO), or other oxide semiconductor materials composed of mixtures of the above-mentioned materials, but the present invention is not limited to this. Additionally, steps of forming the patterned oxide semiconductor layer 13 may include vacuum deposition, spin-on coating, inkjet printing, screen printing, or other appropriate manufacturing approaches.

The following description will detail the different embodiments of the thin film transistor and the manufacturing method thereof in the present invention. To simplify the description, the identical components in each of the following embodiments are marked with identical symbols. For making it easier to compare the difference between the embodiments, the following description will detail the dissimilarities among different embodiments and the identical features will not be redundantly described.

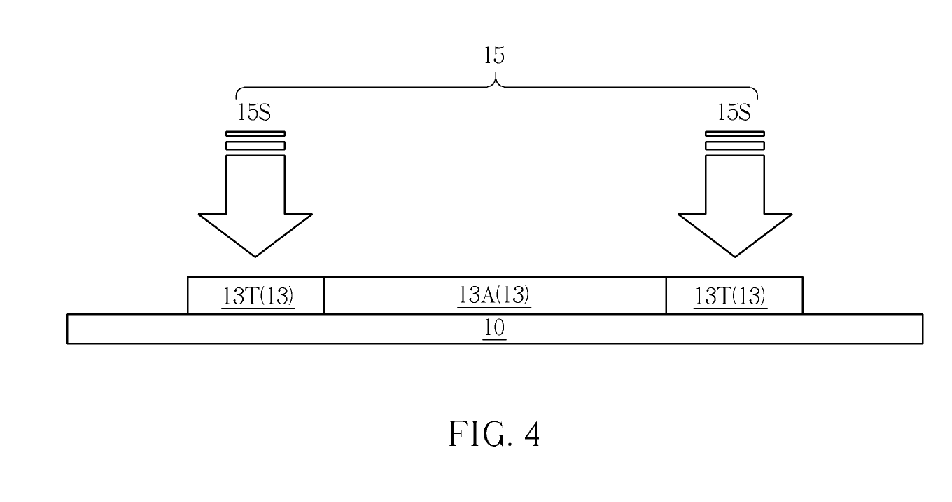

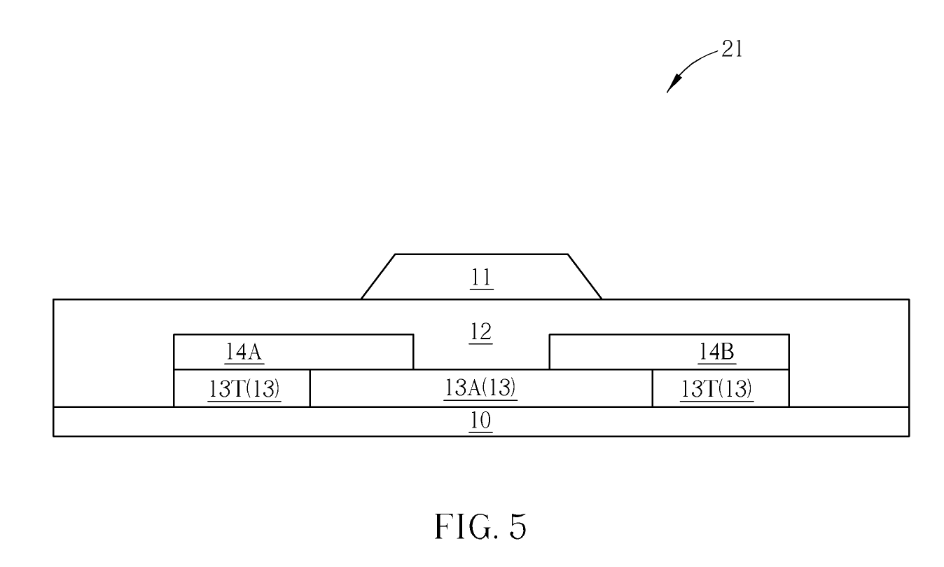

Please refer to FIGS. 4-5. FIGS. 4-5 are schematic diagrams illustrating a manufacturing method of a thin film transistor according to the second preferred embodiment of the present invention. In this embodiment, a thin film transistor 21 is a staggered thin film transistor. As shown in FIGS. 4-5, the manufacturing method of this embodiment includes following steps. Firstly, a substrate 10 is provided. A patterned oxide semiconductor layer 13 is formed on the substrate 10. A localized laser treatment 15 is then executed on parts of the patterned oxide semiconductor layer 13. A laser beam 15S is employed to irradiate parts of the patterned oxide semiconductor layer 13. In this embodiment, the patterned oxide semiconductor layer 13 within a region 13T is irradiated by the laser beam 15S, and the patterned oxide semiconductor layer 13 within a region 13A is not irradiated by the laser beam 15S. The electrical resistitivity of the patterned oxide semiconductor layer 13 within the region 13T is lower than the electrical resistitivity of the patterned oxide semiconductor layer 13 within the region 13A. As shown in FIG. 5, a source electrode 14A and a drain electrode 14B are then formed on the substrate 10. At least a part of the patterned oxide semiconductor layer 13 within the region 13T contacts the source electrode 14A or the drain electrode 14B. A gate insulating layer 12 is then formed and covers the substrate 10, the source electrode 14A, the drain electrode 14B, and the patterned oxide semiconductor layer 13. A gate electrode 11 is then formed on the gate insulating layer 12. It is worth noticing that, in this embodiment, the source electrode 14A and the drain electrode 14B entirely cover the patterned oxide semiconductor layer 13 within the region 13T and partially cover the patterned oxide semiconductor layer 13 within the region 13A. In other embodiments of the present invention, the source electrode 14A and the drain electrode 14B may partially cover the patterned oxide semiconductor layer 13 within the region 13T or the source electrode 14A and the drain electrode 14B may extend to contact the substrate 10.

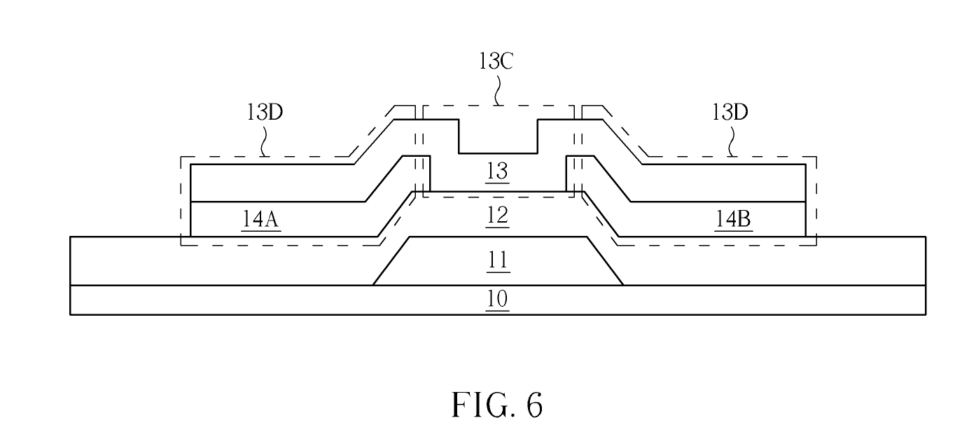

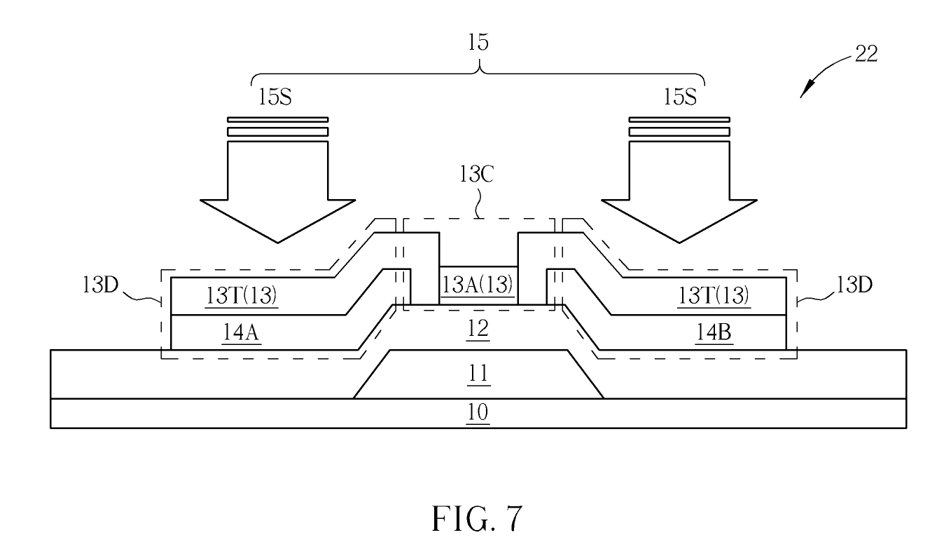

Please refer to FIGS. 6-7. FIGS. 6-7 are schematic diagrams illustrating a manufacturing method of a thin film transistor according to the third preferred embodiment of the present invention. In this embodiment, a thin film transistor 22 is an inverted coplanar thin film transistor. As shown in FIGS. 6-7, the manufacturing method of this embodiment includes following steps. Firstly, a substrate 10 is provided. A gate electrode 11 is then formed on the substrate 10. A gate insulating layer 12 is formed and covers the gate electrode 11 and the substrate 10. A source electrode 14A and a drain electrode 14B are then formed on the gate insulating layer 12. A patterned oxide semiconductor layer 13 is then formed on the gate insulating layer 12, the source electrode 14A, and the drain electrode 14B. Subsequently, as shown in FIG. 7, a localized laser treatment 15 is then executed. A laser beam 15S is employed to irradiate parts of the patterned oxide semiconductor layer 13. In this embodiment, the patterned oxide semiconductor layer 13 within a region 13T is irradiated by the laser beam 15S, and the patterned oxide semiconductor layer 13 within a region 13A is not irradiated by the laser beam 15S. The electrical resistitivity of the patterned oxide semiconductor layer 13 within the region 13T is lower than the electrical resistitivity of the patterned oxide semiconductor layer 13 within the region 13A. As shown in FIG. 6, in this embodiment, the patterned oxide semiconductor layer 13 entirely covers the source electrode 14A and the drain electrode 14B, and the patterned oxide semiconductor layer 13 entirely covers the gate insulating layer 12 between the source electrode 14A and the drain electrode 14B. In other embodiments of the present invention, based on different design considerations, the patterned oxide semiconductor layer 13 may partially cover the source electrode 14A and the drain electrode 14B, and the patterned oxide semiconductor layer 13 may partially cover the gate insulating layer 12 between the source electrode 14A and the drain electrode 14B. Additionally, in this embodiment, a channel region 13C includes at least the patterned oxide semiconductor layer 13 disposed on the gate insulating layer 12 between the source electrode 14A and the drain electrode 14B, and a non-channel region 13D includes the patterned oxide semiconductor layer 13 outside the channel region 13C. It is worth noticing that, as shown in FIG. 7, the patterned oxide semiconductor 13 within the region 13T, which is irradiated by the laser beam 15S, includes the patterned oxide semiconductor 13 within the non-channel region 13D and a part of the patterned oxide semiconductor 13 within the channel region 13C. The range of the region 13T may be controlled by simply modifying process parameters of the localized laser treatment 15. Therefore, in other embodiments of the present invention, the patterned oxide semiconductor 13 within the region 13T may only include a part of the patterned oxide semiconductor 13 within the non-channel region 13D, or the patterned oxide semiconductor 13 within the region 13T may include a part of the patterned oxide semiconductor 13 within the channel region 13C and a part of the patterned oxide semiconductor 13 within the non-channel region 13D. The range of the region 13T may be modified by controlling the localized laser treatment 15, according to different considerations such as process complexity and electrical performance.

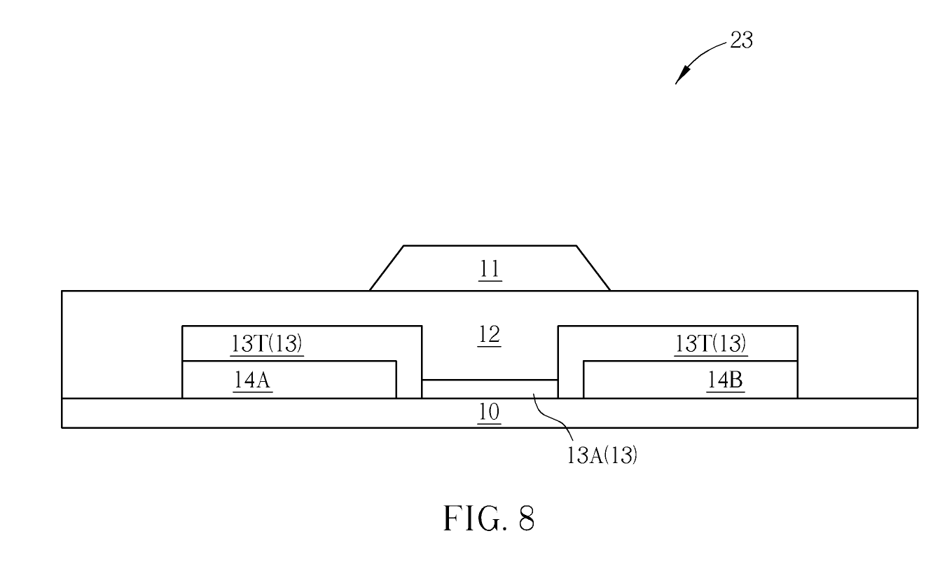

Please refer to FIG. 8. FIG. 8 is a schematic diagram illustrating a thin film transistor according to the fourth preferred embodiment of the present invention. In this embodiment, a thin film transistor 23 is a coplanar thin film transistor. As shown in FIG. 8, the manufacturing method of this embodiment includes following steps. Firstly, a substrate 10 is provided. A source electrode 14A and a drain electrode 14B are then formed on the substrate 10. Subsequently, a patterned oxide semiconductor layer 13 is formed and a localized laser treatment 15 (not shown) is then executed on parts of the patterned oxide semiconductor layer 13. A laser beam 15S (not shown) is employed to irradiate parts of the patterned oxide semiconductor layer 13. In this embodiment, the patterned oxide semiconductor layer 13 within a region 13T is irradiated by the laser beam 15S, and the patterned oxide semiconductor layer 13 within a region 13A is not irradiated by the laser beam 15S. The electrical resistitivity of the patterned oxide semiconductor layer 13 within the region 13T is lower than the electrical resistitivity of the patterned oxide semiconductor layer 13 within the region 13A. A gate insulating layer 12 is then formed and covers the substrate 10 and the patterned oxide semiconductor layer 13. A gate electrode 11 is then formed on the gate insulating layer 12. As shown in FIG. 8, in this embodiment, the patterned oxide semiconductor layer 13 entirely covers the source electrode 14A and the drain electrode 14B, and the patterned oxide semiconductor layer 13 entirely covers the substrate 10 between the source electrode 14A and the drain electrode 14B. In other embodiments of the present invention, based on different design considerations, the patterned oxide semiconductor layer 13 may partially cover the source electrode 14A and the drain electrode 14B, and the patterned oxide semiconductor layer 13 may partially cover the substrate 10 between the source electrode 14A and the drain electrode 14B. In addition, the range of the region 13T and the method of controlling the region 13T in this embodiment are similar to those in the third preferred embodiment and will not be redundantly described.

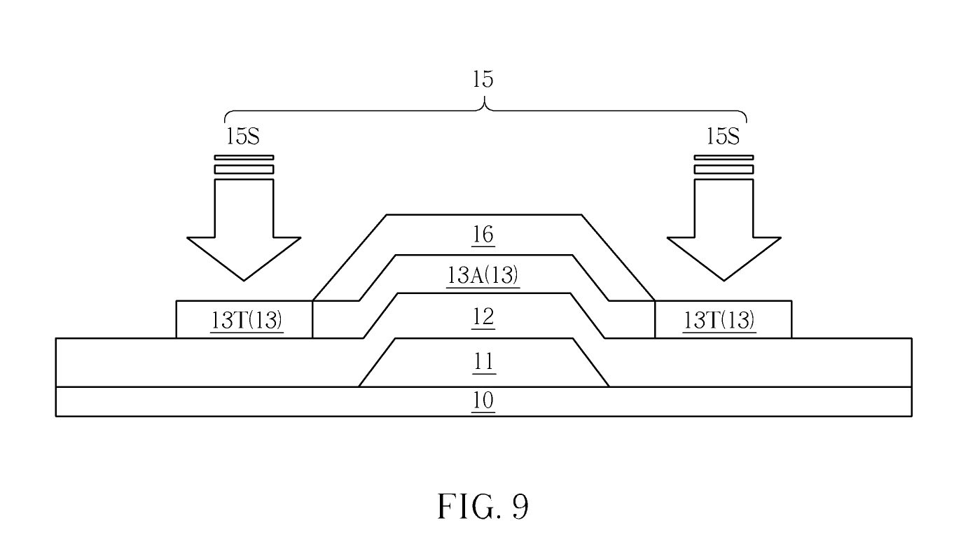

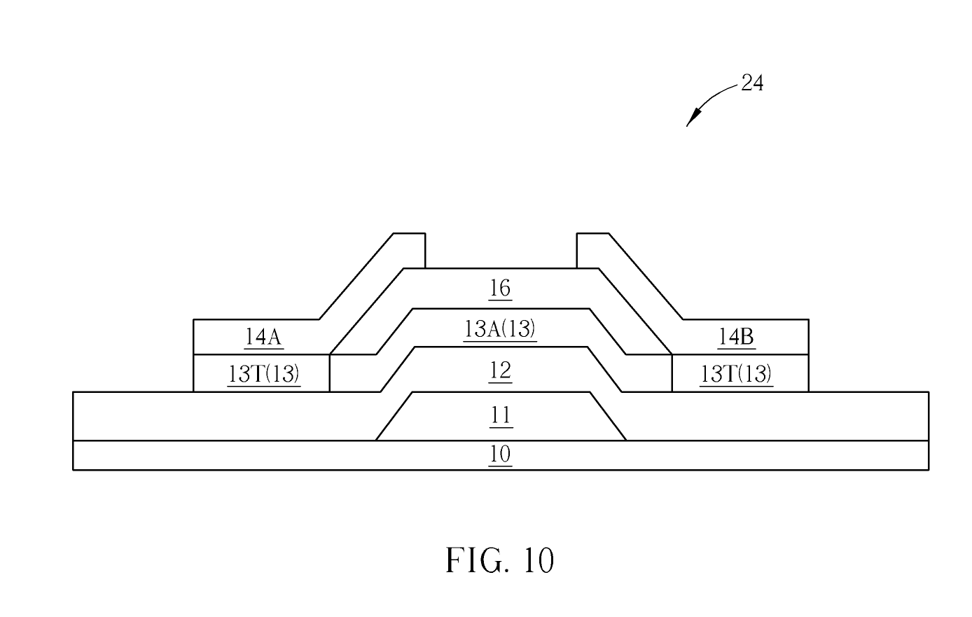

Please refer to FIGS. 9-10. FIGS. 9-10 are schematic diagrams illustrating a manufacturing method of the thin film transistor according to a fifth preferred embodiment of the present invention. In this embodiment, a thin film transistor 24 is an inverted staggered thin film transistor with an etching stop structure. As shown in FIGS. 9-10, the manufacturing method of this embodiment includes following steps. Firstly, a substrate 10 is provided. A gate electrode 11 is then formed on the substrate 10. A gate insulating layer 12 is formed and covers the gate electrode 11 and the substrate 10. A patterned oxide semiconductor layer 13 is then formed on the gate insulating layer 12. Subsequently, a patterned passivation layer 16 is then formed on the patterned oxide semiconductor layer 13. The patterned passivation layer 16 covers at least a part of the patterned oxide semiconductor layer 13. As shown in FIG. 9, a localized laser treatment 15 is then executed on parts of the patterned oxide semiconductor layer 13. A laser beam 15S is employed to irradiate parts of the patterned oxide semiconductor layer 13. In this embodiment, the patterned oxide semiconductor layer 13 within a region 13T is irradiated by the laser beam 15S, and the patterned oxide semiconductor layer 13 within a region 13A is not irradiated by the laser beam 15S. The electrical resistitivity of the patterned oxide semiconductor layer 13 within the region 13T is lower than the electrical resistitivity of the patterned oxide semiconductor layer 13 within the region 13A. As shown in FIG. 10, a source electrode 14A and a drain electrode 14B are then formed. At least a part of patterned the oxide semiconductor layer 13 within the region 13T contacts the source electrode 14A or the drain electrode 14B. In this embodiment, the source electrode 14A and the drain electrode 14B entirely cover the patterned oxide semiconductor layer 13 within the region 13T, and the source electrode 14A and the drain electrode 14B do not cover the patterned oxide semiconductor layer 13 within the region 13A. In other embodiments of the present invention, the source electrode 14A and the drain electrode 14B may partially cover the patterned oxide semiconductor layer 13 within the region 13T or the source electrode 14A and the drain electrode 14B may extend to contact the gate insulating layer 12. It is worth noticing that, in this embodiment, the patterned oxide semiconductor layer 13 within the region 13T includes the entire patterned oxide semiconductor layer 13 which is not covered by the patterned passivation layer 16. The localized laser treatment 15 may be selectively executed on specific regions. Therefore, in other embodiments of the present invention, the patterned oxide semiconductor layer 13 within the region 13T may include only a part of the patterned oxide semiconductor layer 13 which is not covered by the patterned passivation layer 16 according to different design considerations. In addition, the patterned passivation layer 16 in this embodiment may also be employed to protect a part of the patterned oxide semiconductor layer 13 during an etch process for forming the source electrode 14A and the drain electrode 14B, especially when a selectivity of the etching process is relatively low. The patterned passivation layer 16 may further be employed to protect a region of the patterned oxide semiconductor layer 13, whose electrical resistivity is not supposed to be lowered, from influences of the localized laser treatment 15. The influence generated by process variations of the localized laser treatment 15 may also be controlled under the structure mentioned above, and the electrical performance of the thin film transistor in the present invention may be further ensured.

In the present invention, the localized laser treatment, which may be may be selectively executed on specific regions, is employed to selectively lower the electrical resistivity of the oxide semiconductor layer within specific regions. The purpose of lowering the contact resistance between the oxide semiconductor layer and the source/drain electrodes and enhancing the performance of the oxide semiconductor thin film transistor may then be achieved. Additionally, the restriction of the adequate materials for the source/drain electrodes in the oxide semiconductor thin film transistor may be further relaxed, and the flexibility of the manufacturing process may also be enhanced.

Those skilled in the art will readily observe that numerous modifications and alterations of the device and method may be made while retaining the teachings of the invention.

What is claimed is:

1. A manufacturing method of a thin film transistor, comprising:
providing a substrate;
forming a gate electrode on the substrate;
forming a gate insulating layer on the substrate;
forming a patterned oxide semiconductor layer on the substrate;
forming a source electrode and a drain electrode on the substrate; and
executing a localized laser treatment, the localized laser treatment employing a laser beam to irradiate at least a part of the patterned oxide semiconductor layer, wherein an electrical resistitivity of the patterned oxide semiconductor layer irradiated by the laser beam is lower than an electrical resistitivity of the patterned oxide semiconductor layer without being irradiated by the laser beam, and at least a part of the patterned oxide semiconductor layer irradiated by the laser beam contacts the source electrode or the drain electrode.

2. The manufacturing method of the thin film transistor of claim 1, wherein the source electrode and the drain electrode are formed before forming the patterned oxide semiconductor layer, and the localized laser treatment is executed before forming the source electrode and the drain electrode.

3. The manufacturing method of the thin film transistor of claim 1, wherein the patterned oxide semiconductor layer is formed before forming the source electrode and the drain electrode, and the localized laser treatment is executed after forming the source electrode and the drain electrode.

4. The manufacturing method of the thin film transistor of claim 1, wherein the patterned oxide semiconductor layer includes II-VI compounds.

5. The manufacturing method of the thin film transistor of claim 4, wherein the patterned oxide semiconductor layer further includes at least one of alkaline-earth metals, IIIA compounds, VA compounds, VIA compounds, or transition metals.

6. The manufacturing method of the thin film transistor of claim 4, wherein steps of forming the patterned oxide semiconductor layer include vacuum deposition, spin-on coating, inkjet printing, or screen printing.

7. The manufacturing method of the thin film transistor of claim 1, wherein the substrate includes a rigid substrate or a flexible substrate.

8. The manufacturing method of the thin film transistor of claim 7, wherein the rigid substrate includes a glass substrate.

9. The manufacturing method of the thin film transistor of claim 1, wherein a wavelength range of the laser beam in the localized laser treatment is between 250 nanometers and 500 nanometers.

10. The manufacturing method of the thin film transistor of claim 1, further comprising forming a patterned passivation layer on the patterned oxide semiconductor layer for protecting a part of the semiconductor layer from being influenced by the localized laser treatment, wherein the patterned passivation layer is formed before forming the source electrode and the drain electrode, and the localized laser treatment is executed before forming the source electrode and the drain electrode.
